(19) United States
(12) Patent Application Publication
(10) Pub. No.: US 2008/0009143 A1
(43) Pub. Date: Jan. 10, 2008

(54) Method of forming silicon oxide layer

(76) Inventors: Nobuhide Yamada, Tokyo (JP); Rempei Nakata, Kamakura-shi (JP); Yukio Nishiyama, Yokkaichi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/819,275

(22) Filed: Jun. 26, 2007

(30) Foreign Application Priority Data
Jun. 27, 2006 (JP) 2006-176041

(51) Int. Cl. H01L 21/31

(52) U.S. Cl. 438/787; 438/788; 257/E21.278

(57) ABSTRACT

Disclosed is a method of forming a silicon oxide layer comprising: supplying at least a gas containing Si as a raw gas to a semiconductor substrate having a recess formed on its surface to form a primary reactant on the surface, then performing dehydration condensation to form a silicon oxide layer above the semiconductor substrate; removing a part of the silicon oxide layer until a portion of the silicon oxide layer formed in the recess that has a lower density than the silicon oxide layer formed in a vicinity of the surface is at least partially exposed; and supplying a gas containing Si to the silicon oxide layer having a lower density.

### CROSS-REFERENCE TO RELATED APPLICATION

This application is based on and claims the benefit of priority from the prior Japanese Patent Application No. 2006-176041, filed on Jun. 27, 2006, the entire contents of which are incorporated herein by reference.

### BACKGROUND OF THE INVENTION

1. Field of the Invention

The present invention relates to a method of forming a silicon oxide layer above a semiconductor substrate having a recess formed on its surface.

2. Description of the Related Art

There are several conventional methods of forming a silicon oxide layer on a semiconductor substrate having a recess formed on its surface, the recess being such as a shallow trench isolation (STI). One common method is to form a primary reactant on the semiconductor substrate and then perform dehydration condensation to form the silicon oxide layer. One such method is the condensation CVD method.

The condensation CVD method is described as follows. A gas containing Si, including silane (SiH₄) or organic silane such as tetraethoxysilane (TEOS) or methylsilane, and an oxygen source gas such as hydrogen peroxide (H₂O₂) or an ozone gas are used as a raw gas. The raw gas are used to form silanol having fluidity on the semiconductor substrate and then the dehydration condensation is performed, thereby forming the silicon oxide layer (see, for example, JPH 9-251997 and JP 2002-83864).

When, for example, SiH₄ and H₂O₂ are used as a raw gas, the SiH₄ and H₂O₂ are first subject to the silanolization reaction to form silanol (Si(OH)₄) as the primary reactant on the semiconductor substrate. Because the silanol is highly fluid, even a narrow recess can be filled flatly. The substrate is then heated (cured) in a vacuum at, for example, 350° C. in the same manufacturing equipment. The dehydration condensation reaction is thus facilitated according to formula 1, forming the silicon oxide layer,

Formula 1
Si(OH)₄→SiO₂+2H₂O

The condensation CVD method exhibits better embeddability than the HDP-CVD. The method provides, however, an insufficient withstand voltage of the silicon oxide layer embedded in the recess. The insufficient with stand voltage may degrade the characteristics of the semiconductor device.

### SUMMARY OF THE INVENTION

A method of forming a silicon oxide layer according to a first aspect of the present invention comprises: supplying at least a gas containing Si as a raw gas to a semiconductor substrate having a recess formed on its surface to form a primary reactant on the surface, then performing dehydration condensation to form a silicon oxide layer above the semiconductor substrate; removing a part of the silicon oxide layer until a portion of the silicon oxide layer formed in the recess that has a lower density than the silicon oxide layer formed in a vicinity of the surface is at least partially exposed; and supplying a gas containing Si to the silicon oxide layer having a lower density.

A method of forming a silicon oxide layer according to a second aspect of the present invention comprises supplying at least a gas containing Si as a raw gas to a semiconductor substrate having a recess formed on its surface to form a primary reactant on the surface, then performing dehydration condensation to form a silicon oxide layer above the semiconductor substrate, wherein an energy beam is applied during the primary reactant is formed.

A method of forming a silicon oxide layer according to a third aspect of the present invention comprises supplying at least a gas containing Si as a raw gas to a semiconductor substrate having a recess formed on its surface to form a primary reactant on the surface, then performing dehydration condensation to form a silicon oxide layer above the semiconductor substrate, wherein a dehydration condensation accelerator is supplied during the primary reactant is formed.

A method of forming a silicon oxide layer according to a fourth aspect of the present invention comprises supplying at least a gas containing Si as a raw gas to a semiconductor substrate having a recess formed on its surface to form a primary reactant on the surface, then performing dehydration condensation to form a silicon oxide layer on the semiconductor substrate, Wherein the semiconductor substrate is heated while exposing the primary reactant to oxygen plasma after the primary reactant is formed.

### BRIEF DESCRIPTION OF THE DRAWINGS

FIG. 1 is a schematic diagram of manufacturing equipment used to implement a method of forming a silicon oxide layer according to a first embodiment of the present invention.

FIG. 2 is a cross sectional view of a semiconductor substrate before a silicon oxide layer is formed according to a first embodiment.

FIG. 3 is a cross sectional view of a semiconductor substrate when a silicon oxide layer is formed according to a first embodiment.

FIG. 4 is a cross sectional view of a semiconductor substrate when a silicon oxide layer is formed according to a first embodiment.

FIG. 5 is a cross sectional view of a semiconductor substrate after a silicon oxide layer is formed according to a first embodiment.

FIG. 6 is a schematic diagram of manufacturing equipment used to implement a method of forming a silicon oxide layer according to a second embodiment of the present invention.

FIG. 7 is a cross sectional view of a semiconductor substrate before a silicon oxide layer is formed according to a second embodiment.

FIG. 8 is a cross sectional view of a semiconductor substrate when a silicon oxide layer is being formed according to a second embodiment.

FIG. 9 is a cross sectional view of a semiconductor substrate after a silicon oxide layer is formed according to a second embodiment.

FIG. 10 is a cross sectional view of a semiconductor substrate before a silicon oxide layer is formed according to a third embodiment.

FIG. 11 is a cross sectional view of a semiconductor substrate when a silicon oxide layer is formed according to a third embodiment.

FIG. 12 is a cross sectional view of a semiconductor substrate after a silicon oxide layer is formed according to a third embodiment.

FIG. 13 is a schematic diagram of manufacturing equipment used to implement a method of forming a silicon oxide layer according to a fourth embodiment of the present invention.

FIG. 14 is a cross sectional view of a semiconductor substrate before a silicon oxide layer is formed according to a fourth embodiment.

FIG. 15 is a cross sectional view of a semiconductor substrate after a silicon oxide layer is formed according to a fourth embodiment.

### DETAILED DESCRIPTION OF THE EMBODIMENTS

### First Embodiment

A method of forming a silicon oxide layer according to a first embodiment of the present invention will be described in detail with reference to the accompanying drawings. FIG. 1 is a schematic diagram of manufacturing equipment to implement a method of forming a silicon oxide layer according to the first embodiment. The manufacturing equipment includes a reaction chamber 10, a semiconductor substrate holder 12 that holds a semiconductor substrate, the holder 12 being disposed in the reaction chamber 10, a cooling tube 14 that cools a semiconductor substrate 22 held on the semiconductor substrate holder 12, the substrate 22 being to be cooled to, for example, 0 to 5° C., an exhaust port 16 that exhausts gas in the reaction chamber 10, and supply openings 18 and 20 that supply raw gas into the reaction chamber 10.

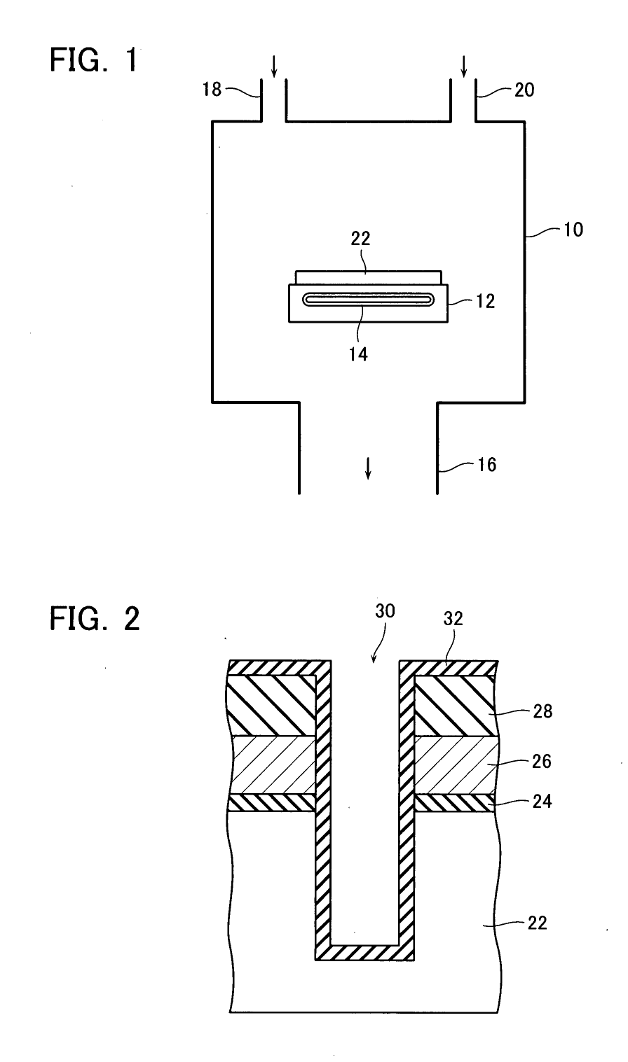

A description is now given of a method of forming a silicon oxide layer according to the first embodiment using the above manufacturing equipment. Referring to FIG. 2, the semiconductor substrate 22 is first provided with a tunnel oxide layer 24 formed thereon, on which an electrode such as a poly-Si layer 26 is formed, on which a mask layer 28 for use during processing is deposited, on which a shallow trench isolation (STI) 30 is formed by a process such as an etching, on which a thin silicon oxide layer 32 is formed by thermal CVD method. The semiconductor substrate 22 thus processed is then disposed in the manufacturing equipment on the semiconductor substrate holder 12.

With the semiconductor substrate 22 being cooled to, for example, 0 to 5° C., the condensation CVD method is implemented, using a gas containing Si such as SiH₄ and an oxygen source gas such as H₂O₂ as the raw gas, to form silanol, filling the STI 30. Specifically, the SiH₄ and H₂O₂ are supplied through the supply openings 18 and 20 into the reaction chamber 10. The SiH₄ and H₂O₂ may cause a silanolization reaction (such as SiH₄+4H₂O₂→Si(OH)₄+4H₂O). The reaction forms the silanol over the semiconductor substrate having the thin silicon oxide layer 32 formed thereon. Although in the first embodiment, the semiconductor substrate 22 is cooled to 0 to 5° C. as described above, the semiconductor substrate 22 may be maintained at a temperature range from −10 to 15° C. This temperature range is acceptable to allow silanol having fluidity to adhere to the substrate surface, allowing silanol to fill closely the STI 30. Then, under the vacuum condition, the semiconductor substrate 22 is transferred to another reaction chamber (not shown). In the chamber, the substrate 22 is heated (cured) in a vacuum by a heater and the like at, for example, 350° C. The dehydration condensation reaction is thus facilitated, forming the silicon oxide layer on the substrate 22.

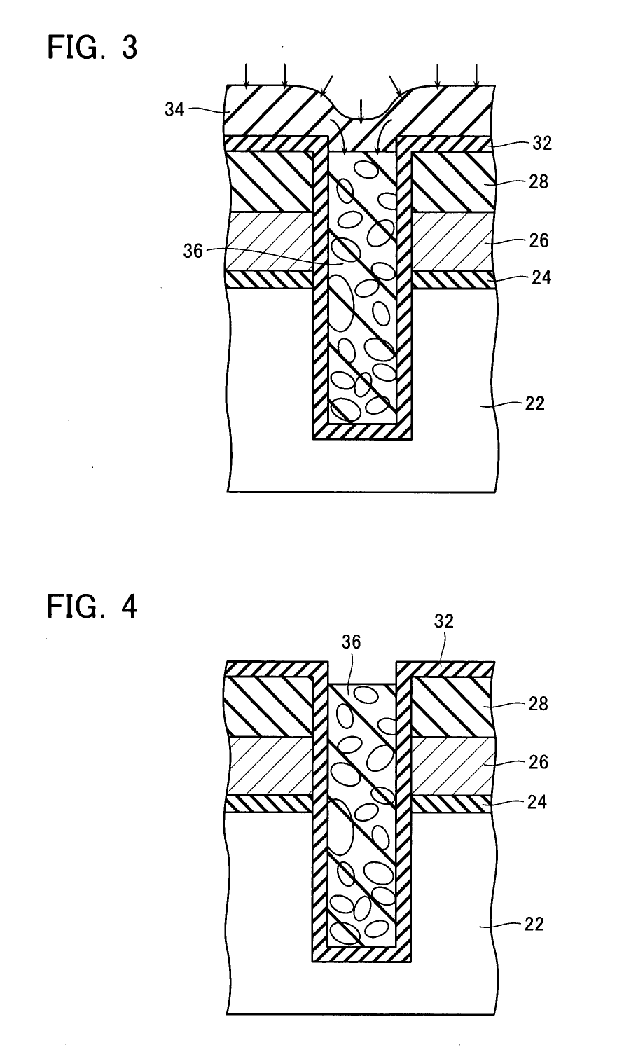

The silicon oxide layer thus formed by the condensation CVD method undergoes volume contraction from the dehydration condensation. Referring to FIG. 3, the vicinity of the surface contracts vertically and the vicinity of the surface of the groove receives inflow from the surface, thus forming a dense layer 34. Some portions within the STI 30 cannot, however, change their volume, causing a density reduction or a density nonuniformity, which forms a lower density area 36. An improvement process of the lower density area 36 may be hampered by the dense layer 34. The dense layer 34 is therefore removed, as shown in FIG. 4, by dry etching such as RIE. This thus exposes the lower density area 36 of the silicon oxide layer within the STI 30. The lower density area 36 may be exposed for example as follows. The reaction chamber 10 is provided with a plasma generation portion (not shown) therein. The reaction chamber 10 is filled with NF₃ gas. The NF₃ gas is ionized by the plasma generation portion into a plasma. The condition in which the plasma cleans the reaction chamber 10 may be used to expose the lower density area 36.

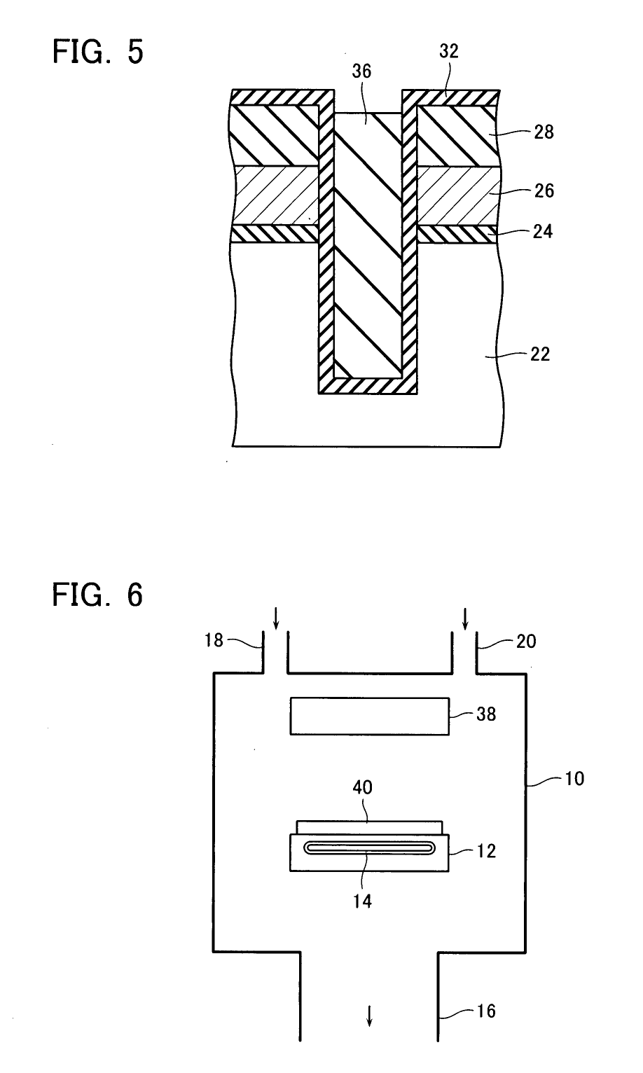

The lower density area 36 is then subject to improvement. The improvement may start with supplying SiH₄ into the reaction chamber 10 to impregnate the lower density area 36 with SiH₄. The lower density area 36 has more remaining uncross-linked Si—OH groups than the dense layer 34. With no H₂O₂ being supplied, therefore, SiH₄ impregnated into the lower density area 36 may react with the uncross-linked Si—OH groups, forming SiO₂. The lower density area 36 may thus reduce its density nonuniformity, as shown in FIG. 5, and be improved to be the dense silicon oxide layer. The semiconductor substrate 22 may then be heated (annealed) by an electric furnace and the like at, for example, 900° C. This may further facilitate the cross-linking of the silicon oxide layer or develop the three-dimensional framework of the layer.

Note that the steps to form silanol and the subsequent steps such as the curing process may be performed in the same manufacturing equipment. The method of forming a silicon oxide layer according to the first embodiment may be applied not only to fill the STI but also to fill between Al lines formed by RIE and the like. In the method of forming a silicon oxide layer according to the first embodiment, the improvement may not use the gas containing Si that is used to form the silanol, and may use different gas containing Si such as organic silane such as TEOS or methylsilane.

The condensation CVD method generally exhibits better embeddability. The method undergoes, however, volume contraction from the dehydration condensation reaction after silanol is formed, filling the recesses. The volume contraction may cause the density reduction of the silicon oxide layer that is embedded into the recesses by the condensation CVD method. The volume contraction may also cause a density nonuniformity of the silicon oxide layer in the recesses. The recesses may thus have a lower density area formed therein. The volume contraction may also peel the silicon oxide layer off the inside of the recesses. Particularly, such problems have become more pronounced as the recess becomes smaller or the aspect ratio (depth/opening width of the groove) becomes larger. When, as described above, the silicon oxide layer has the lower density area formed therein or experiences peeling, the resistance to chemical solution may reduce or roughness may occur after the processings. The subsequent processings may thus be adversely affected, or the withstand voltage may be reduced, thereby degrading the characteristics of the semiconductor device. Such problems may be solved by the method of forming a silicon oxide layer according to the first embodiment by improving the lower density area to reduce the density nonuniformity in the lower density area, thereby improving the layer to be the dense silicon oxide layer.

### Second Embodiment

A method of forming a silicon oxide layer according to a second embodiment of the present invention will be described in detail with reference to the accompanying drawings. FIG. 6 is a schematic diagram of manufacturing equipment to implement a method of forming a silicon oxide layer according to the second embodiment. The manufacturing equipment is configured in the same way as that in the first embodiment except that the reaction chamber 10 contains a microwave irradiation portion 38 that applies a microwave.

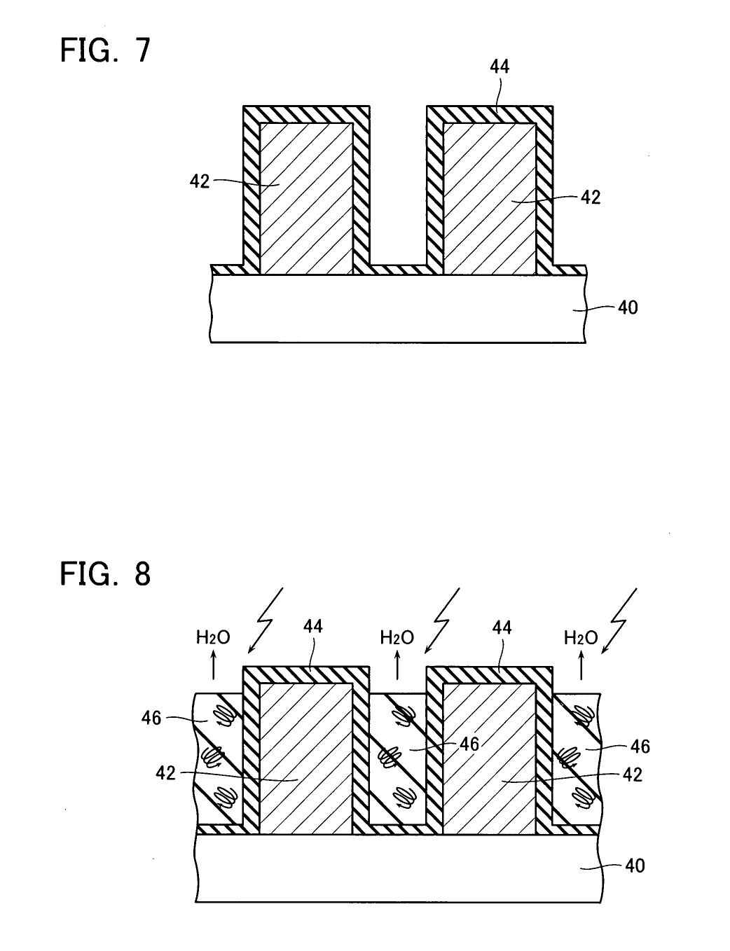

A description is now given of a method of forming a silicon oxide layer according to the second embodiment using the manufacturing equipment. Referring to FIG. 7, the semiconductor substrate 40 is first provided with a plurality of Al lines 42 formed thereon by RIE, on which SiON layer 44 to prevent corrosion is formed by PE CVD method. The semiconductor substrate 40 thus processed is then disposed in the manufacturing equipment on the semiconductor substrate holder 12.

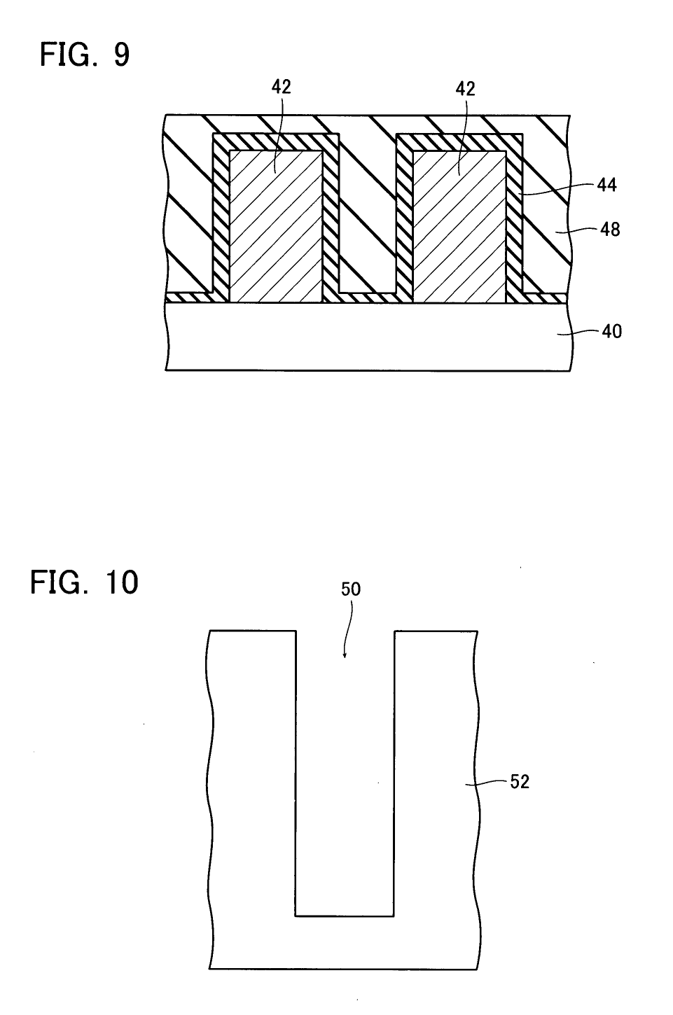

The condensation CVD method is implemented, using SiH₄ and H₂O₂ as the raw gas, to form a silicon oxide layer, filling between the Al lines 42. The method of forming a silicon oxide layer according to the second embodiment differs from the that of the first embodiment in that during the silanol is formed, the microwave irradiation portion 38 applies the microwave in the reaction chamber 10. Referring to FIG. 8, when the microwave is applied, the silanol 46 that is formed by the silanolization reaction and is embedded between the Al lines 42 has its Si—OH groups activated, the silanol and silicon oxide molecules are stirred, and the dehydration condensation reaction is facilitated. Then, the semiconductor substrate 22 is transferred to another reaction chamber (not shown). In the chamber, the substrate 22 is heated (cured) in a vacuum by a heater and the like at, for example, 350° C. The dehydration condensation reaction is thus further facilitated. This may form, as shown in FIG. 9, a homogeneous and dense silicon oxide layer 48 between the Al lines 42. The semiconductor substrate 22 may then be heated (annealed) by an electric furnace and the like at, for example, 900° C. This may further facilitate the cross-linking of the silicon oxide layer or develop the three-dimensional framework of the layer.

As described above, in the method of forming a silicon oxide layer according to the second embodiment, the silicon oxide layer is formed by the condensation CVD method using the application of the microwave. Alternatively, however, an electron beam irradiation portion or an ultraviolet light irradiation portion may be provided, for example, to apply the electron beam or ultraviolet light. The method of forming a silicon oxide layer according to the second embodiment may be applied not only to fill the recess but also to form, on a flat substrate, a dense silicon oxide layer. Further, the method of forming a silicon oxide layer according to the second embodiment may be applied not only to fill between the Al lines formed by RIE but also to fill the STI and the like.

The problems with the condensation CVD described above may be solved by the method of forming a silicon oxide layer according to the second embodiment by forming the primary reactant such as silanol using the application of the energy beam, thereby forming the homogeneous and dense silicon oxide layer.

### Third Embodiment

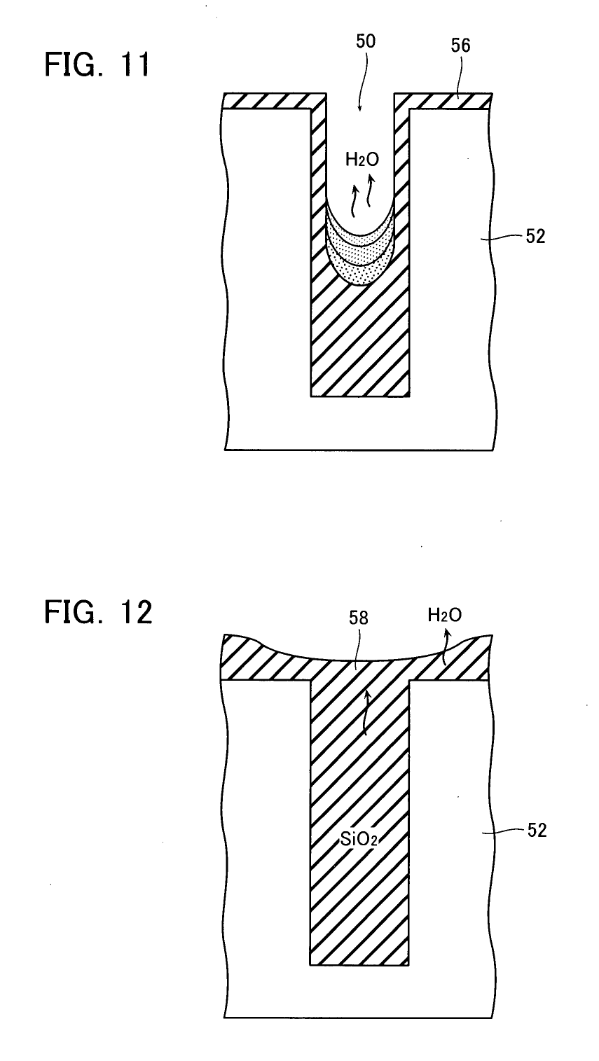

A method of forming a silicon oxide layer according to a third embodiment of the present invention will be described in detail with reference to the accompanying drawings. The manufacturing equipment is the same as that used in the first embodiment. Referring to FIG. 10, a process such as an etching is used to form a shallow trench isolation (STI) 50 on a semiconductor substrate 52. The semiconductor substrate 52 thus processed is then disposed in the manufacturing equipment on the semiconductor substrate holder 12. The condensation CVD method is implemented, using SiH₄ and H₂O₂ as the raw gas, to form silanol, filling the STI 50. Note that the third embodiment supplies, in addition to the SiH₄, ammonia as a dehydration condensation accelerator into the reaction chamber 10. When the condensation CVD method is used to fill the STI 50, the ammonia functions as a catalyst that facilitates at low temperatures the dehydration condensation reaction that forms the silicon oxide layer from the silanol. Referring to FIG. 11, the catalyst facilitates the dehydration condensation reactions in a gas phase and on the substrate. Then, the semiconductor substrate 52 is transferred to another reaction chamber (not shown). In the chamber, the substrate 52 is heated (cured) in a vacuum by a heater and the like at, for example, 350° C. The dehydration condensation reaction of the silicon oxide layer is thus further facilitated. This may form, as shown in FIG. 12, the dense silicon oxide layer. The semiconductor substrate 52 may then be heated (annealed) by an electric furnace and the like at, for example, 900° C. This may further facilitate the cross-linking of the silicon oxide layer or develop the three-dimensional framework of the layer.

The method of forming a silicon oxide layer according to the third embodiment may be applied not only to fill the recess but also to form, on a flat substrate, a dense silicon oxide layer. In the method of forming a silicon oxide layer according to the third embodiment, the dehydration condensation accelerator may be, other than the ammonia, a chemical compound including an ammonium group, such as amine such as ethylenediamine. The dehydration condensation accelerator may be supplied after it is dissolved in aqueous solution of H₂O₂ and may then be evaporated. The method of forming a silicon oxide layer according to the third embodiment may be applied not only to fill the STI but also to fill between the Al lines formed by RIE and the like.

The problems with the condensation CVD described above may be solved by the method of forming a silicon oxide layer according to the third embodiment by forming the primary reactant such as silanol using the supply of the dehydration condensation accelerator, thereby forming the homogeneous and dense silicon oxide layer.

### Fourth Embodiment

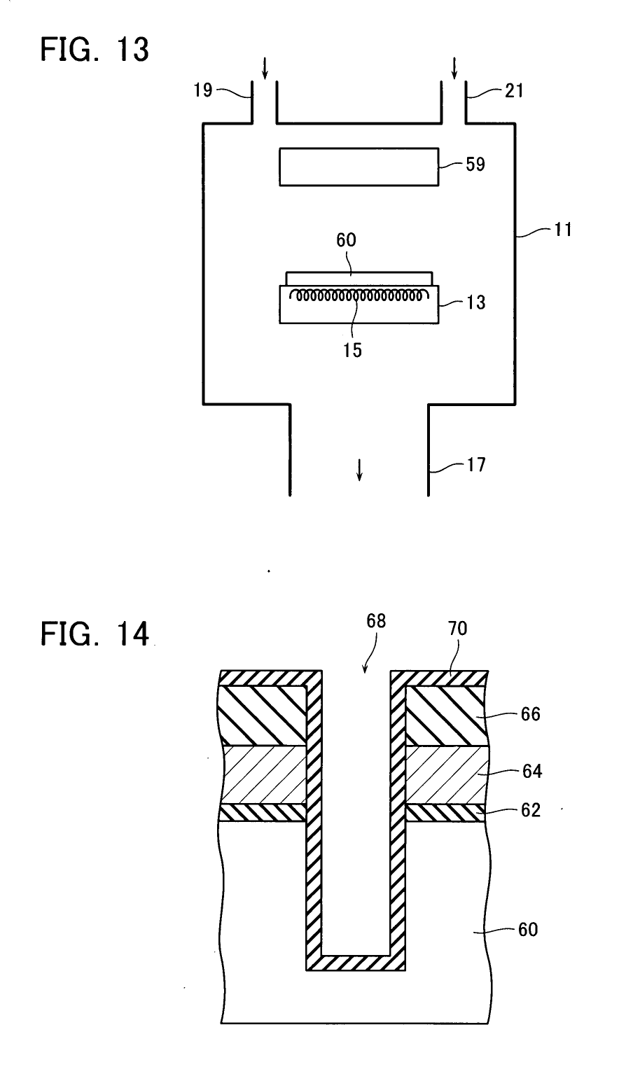

A method of forming a silicon oxide layer according to a fourth embodiment of the present invention will be described. FIG. 13 is a schematic diagram of manufacturing equipment to implement a method of forming a silicon oxide layer according to a fourth embodiment. The manufacturing equipment includes a reaction chamber 11, a semiconductor substrate holder 13 that holds a semiconductor substrate, the holder 13 being disposed in the reaction chamber 11, a heater 15 that heats a semiconductor substrate 60 held on the semiconductor substrate holder 13, an exhaust port 17 that exhausts gas in the reaction chamber 11, supply openings 19 and 21 that supply raw gas into the reaction chamber 11, and a plasma generation portion 59 provided in the reaction chamber 11.

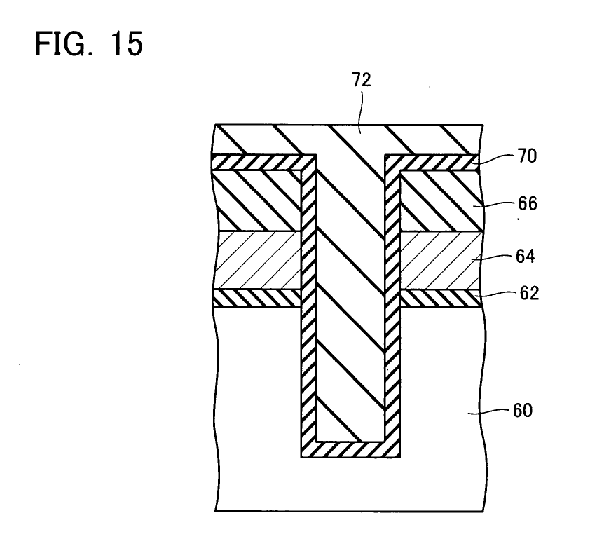

A description is now given of a method of forming a silicon oxide layer according to the fourth embodiment using the manufacturing equipment. Referring to FIG. 14, the semiconductor substrate 60 is first provided with a tunnel oxide layer 62 formed thereon, on which an electrode such as a poly-Si layer 64 is formed, on which a mask layer 66 for use during processing is deposited, on which a shallow trench isolation (STI) 68 is formed by a process such as an etching, on which a thin silicon oxide layer 70 is formed by thermal CVD method. The semiconductor substrate 60 thus processed is then disposed in the manufacturing equipment Used in the first embodiment on the semiconductor substrate holder 12. The condensation CVD method is implemented, using SiH₄ and H₂O₂ as the raw gas, to form silanol, filling the STI 68. Then, under the vacuum condition, the semiconductor substrate 60 is transferred to the reaction chamber 11 shown in FIG. 13. The reaction chamber 11 is filled with oxygen. The plasma generation portion 59 generates oxygen plasma with, for example, a high-frequency electric field applied. With the silanol being exposed to the oxygen plasma, the heater 15 and the like heats the substrate 60 at, for example, 100° C. for one minute for the dehydration condensation (curing process). A silicon oxide layer 72 is thus formed as shown in FIG. 15. The semiconductor substrate 60 may then be heated (annealed) at, for example, 900° C. to further facilitate the cross-linking of the silicon oxide layer or develop the three-dimensional framework of the layer.

In the curing process, the substrate 60 may be exposed to the oxygen plasma, and then be annealed, thereby reducing the volume contraction in the annealing. Compared to the conventional curing process that is performed, for example, under the nitrogen atmosphere, the silicon oxide layer is less likely to be peeled off and to have the lower density area, thereby causing less dissolution during the chemical solution cleaning. Particularly, with the substrate 60 being exposed to the oxygen plasma, the substrate 60 may be heated (cured) more effectively at low temperatures of 300° C. or less, particularly 150° C. or less.

The inventors compared a plurality of silanol layers formed at the same condition by providing the layers with the different curing processes. One layer was subject to the conventional high temperature curing process. Another was the low temperature curing process with the layer being exposed to the oxygen. Still another was the low temperature curing process with the layer being exposed to the oxygen plasma. Specifically, one layer was cured with it being exposed to the nitrogen at 600° C. for two minutes, and was then annealed at 900° C. for one hour. The cured layer thickness was 100 nm and the annealed layer thickness was 90 nm. Another layer was cured with it being exposed to the oxygen at 100° C. for one minute, and was then annealed at 900° C. for one hour. The cured layer thickness was 115 nm and the annealed layer thickness was 95 nm. Still another layer was cured with it being exposed to the oxygen plasma at 250 mTorr and 1000 W at 100° C. for five minutes, and was then annealed at 900° C. for one hour. The cured layer thickness was 110 nm and the annealed layer thickness was 105 nm. Such comparison experiments showed that the lower temperature and shorter time curing process exhibited less volume contraction, and the curing process under exposure to the oxygen plasma exhibited even less volume contraction.

The curing process under exposure to the oxygen plasma may be combined with the above-mentioned first to third embodiments. Specifically, in the first to third embodiments, after the silanol is formed, the curing process may be performed under exposure to the oxygen plasma. The method of forming a silicon oxide layer according to the fourth embodiment may be applied not only to fill the STI, but also to fill between the Al lines formed by RIE and the like. In the method of forming a silicon oxide layer according to the fourth embodiment, the annealing process may be performed at higher temperatures than the curing process.

Note that in the method of forming a silicon oxide layer according to the first to fourth embodiments, the SiH₄ and H₂O₂ are used as the raw gas in the condensation CVD method, but the present invention is not limited thereto. The gas containing Si may include, for example, organic silane such as TEOS or methylsilane, and the oxygen source gas may include ozone gas or the like.

What is claimed is:

1. A method of forming a silicon oxide layer comprising:
supplying at least a gas containing Si as a raw gas to a semiconductor substrate having a recess formed on its surface to form a primary reactant on the surface, then performing dehydration condensation to form a silicon oxide layer above the semiconductor substrate;
removing a part of the silicon oxide layer until a portion of the silicon oxide layer formed in the recess that has a lower density than the silicon oxide layer formed in a vicinity of the surface is at least partially exposed; and
supplying a gas containing Si to the silicon oxide layer having a lower density.

2. The method of forming a silicon oxide layer of claim 1, wherein after the primary reactant is formed, the semiconductor substrate is heated while exposing the primary reactant to oxygen plasma.

3. The method of forming a silicon oxide layer of claim 1, wherein the primary reactant is formed by using the gas containing Si and an oxygen source gas as the raw gas to form silanol having fluidity on the surface.

4. The method of forming a silicon oxide layer of claim 3, wherein after removing the part of the silicon oxide layer, no oxygen source gas is supplied.

5. The method of forming a silicon oxide layer of claim 3, wherein the semiconductor substrate is maintained at a temperature ranging from −10 to 15° C. during the primary reactant is formed.

6. A method of forming a silicon oxide layer, comprising supplying at least a gas containing Si as a raw gas to a semiconductor substrate having a recess formed on its surface to form a primary reactant on the surface, then performing dehydration condensation to form a silicon oxide layer above the semiconductor substrate,
wherein an energy beam is applied during the primary reactant is formed.

7. The method of forming a silicon oxide layer of claim 6, wherein after the primary reactant is formed, the semiconductor substrate is heated while exposing the primary reactant to oxygen plasma.

8. The method of forming a silicon oxide layer of claim 6, wherein the primary reactant is formed by using the gas containing Si and an oxygen source gas as the raw gas to form silanol having fluidity on the surface.

9. The method of forming a silicon oxide layer of claim 6, wherein the energy beam is at least one of a microwave, an electron beam, and ultraviolet light.

10. The method of forming a silicon oxide layer of claim 8, wherein the semiconductor substrate is maintained at a temperature ranging from −10 to 15° C. during the primary reactant is formed.

11. A method of forming a silicon oxide layer, comprising supplying at least a gas containing Si as a raw gas to a semiconductor substrate having a recess formed on its surface to form a primary reactant on the surface, then performing dehydration condensation to form a silicon oxide layer above the semiconductor substrate,
wherein a dehydration condensation accelerator is supplied during the primary reactant is formed.

12. The method of forming a silicon oxide layer of claim 11, wherein after the primary reactant is formed, the semiconductor substrate is heated while exposing the primary reactant to oxygen plasma.

13. The method of forming a silicon oxide layer of claim 11, wherein the primary reactant is formed by using the gas containing Si and an oxygen source gas as the raw gas to form silanol having fluidity on the surface.

14. The method of forming a silicon oxide layer of claim 11, wherein the dehydration condensation accelerator is a chemical compound comprising an ammonium group.

15. The method of forming a silicon oxide layer of claim 13, wherein the semiconductor substrate is maintained at a temperature ranging from −10 to 15° C. during the primary reactant is formed.

16. A method of forming a silicon oxide layer, comprising supplying at least a gas containing Si as a raw gas to a semiconductor substrate having a recess formed on its surface to form a primary reactant on the surface, then performing dehydration condensation to form a silicon oxide layer above the semiconductor substrate,
Wherein the semiconductor substrate is heated while exposing the primary reactant to oxygen plasma after the primary reactant is formed.

17. The method of forming a silicon oxide layer of claim 16, wherein the primary reactant is formed by using the gas containing Si and an oxygen source gas as the raw gas to form silanol having fluidity on the surface.

18. The method of forming a silicon oxide layer of claim 16, wherein the semiconductor substrate is heated to 300° C. or less while exposing the primary reactant to oxygen plasma.

19. The method of forming a silicon oxide layer of claim 16, wherein after being heated while exposing the primary reactant to oxygen plasma, the semiconductor substrate is heated to a higher temperature than when it is heated while exposing the primary reactant to the oxygen plasma.

20. The method of forming a silicon oxide layer of claim 17, wherein the semiconductor substrate is maintained at a temperature ranging from −10 to 15° C. during the primary reactant is formed.
